(19) United States
(12) Patent Application Publication
(10) Pub. No.: US 2010/0258169 A1
(43) Pub. Date: Oct. 14, 2010

(54) PULSED PLASMA DEPOSITION FOR FORMING MICROCRYSTALLINE SILICON LAYER FOR SOLAR APPLICATIONS

(75) Inventors: Shuran Sheng, Santa Clara, CA (US); Yong Kee Chae, Pleasanton, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS , INC., Santa Clara, CA (US)

(21) Appl. No.: 12/422,551

(22) Filed: Apr. 13, 2009

(51) Int. Cl. H01L 31/00; H01L 21/20

(52) U.S. Cl. 136/255; 136/261; 438/488; 257/E21.09

(57) ABSTRACT

A method for an intrinsic type microcrystalline silicon layer is provided. In one embodiment, the microcrystalline silicon layer is fabricated by providing a substrate into a processing chamber, supplying a gas mixture into the processing chamber, applying a RF power at a first mode in the gas mixture, pulsing the gas mixture into the processing chamber, and applying the RF power at a second mode in the pulsed gas mixture.

### BACKGROUND OF THE INVENTION

1. Field of the Invention

Embodiments of the present invention generally relate to solar cells and methods for forming the same. More particularly, embodiments of the present invention relate to a method of forming a microcrystalline silicon layer utilized in solar applications.

2. Description of the Related Art

Photovoltaic devices (PV) or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with specific frames and connectors.

Microcrystalline silicon film (μc-Si) is one type of film being used to form PV devices. However, a production worthy process has yet to be developed to be able to provide PV devices at high deposition rate and high film quality as well as low manufacturing cost. For example, insufficient crystallinity of the silicon film may cause incomplete formation and fraction of the film, thereby reducing the conversion efficiency in a PV solar cell. Additionally, conventional deposition processes of microcrystalline silicon film (μc-Si), have slow deposition rates, which disadvantageously reduce manufacturing throughput and increase production costs.

Therefore, there is a need for an improved method for depositing a microcrystalline silicon film.

### SUMMARY OF THE INVENTION

Embodiments of the invention provide methods for forming solar cells. In one embodiment, a method for forming an intrinsic type microcrystalline silicon layer includes providing a substrate into a processing chamber, supplying a gas mixture into the processing chamber, applying a RF power at a first mode in the gas mixture, pulsing the gas mixture into the processing chamber, and applying the RF power at a second mode in the pulsed gas mixture.

In another embodiment, a method for forming an intrinsic type microcrystalline silicon layer includes providing a substrate into a processing chamber, supplying a gas mixture into the processing chamber, applying a RF power into the gas mixture, depositing a seed silicon layer on the substrate surface, subsequently synchronously pulsing the gas mixture and the RF power supplied to the gas mixture, and depositing a bulk silicon layer over the seed silicon layer.

In yet another embodiment, a photoelectric device includes a p-type silicon containing layer, an intrinsic type microcrystalline silicon layer disposed on the p-type silicon containing layer, and a n-type silicon containing layer disposed on the intrinsic type microcrystalline silicon layer, wherein the intrinsic type microcrystalline silicon layer is formed by a process comprising supplying a gas mixture into the processing chamber having a first RF power mode applied thereto, depositing an intrinsic type microcrystalline silicon seed layer, pulsing the gas mixture in the process chamber having a second RF power mode applied thereto, and depositing a bulk intrinsic type microcrystalline silicon layer over the intrinsic type microcrystalline silicon seed layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a schematic side-view of a tandem junction thin-film solar cell having an intrinsic type microcrystalline silicon layer formed within the solar cell according to one embodiment of the invention;

FIG. 2 is schematic side-view of a single junction thin-film solar cell having an intrinsic type microcrystalline silicon layer formed within the solar cell according to one embodiment of the invention;

FIG. 3 is a cross-sectional view of an apparatus according to one embodiment of the invention;

FIG. 4 is a process flow describing a method to deposit an intrinsic type microcrystalline silicon layer by different RF power during depositing according to one embodiment of the invention;

FIG. 5 is a chart describing a gas flow rate and RF power supplied during deposition of an intrinsic type microcrystalline silicon layer according to one embodiment of the invention; and

FIG. 6 is a plan view of a system having the apparatus of FIG. 3 incorporated therein according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention describes a method to deposit an intrinsic type microcrystalline silicon layer with high deposition rate, high and uniform crystalline fraction, and low manufacturing cost. In one embodiment, the intrinsic type microcrystalline silicon layer may be deposited by a plasma process having a first deposition mode and a second deposition to form an intrinsic type microcrystalline silicon seed layer and a bulk intrinsic type microcrystalline silicon layer respectively. In one embodiment, the intrinsic type microcrystalline silicon layer may be used in a multi-junction solar cell or a single junction solar cell.

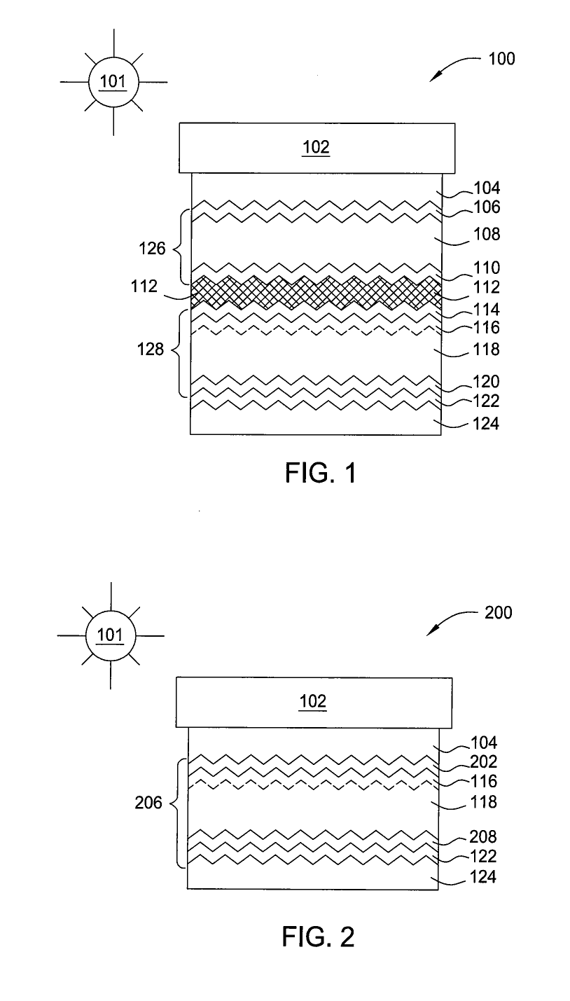

FIG. 1 is a schematic diagram of an embodiment of a multi-junction solar cell 100 oriented toward the light or solar radiation 101. Solar cell 100 comprises a substrate 102, such as a glass substrate, polymer substrate, metal substrate, or other suitable substrate, with thin films formed thereover. The solar cell 100 further comprises a first transparent conducting oxide (TCO) layer 104 formed over the substrate 102 and a first p-i-n junction 126 formed over the first TCO layer 104. In one configuration, an optional wavelength selective reflector (WSR) layer 112 is formed over the first p-i-n junction 126. A second p-i-n junction 128 may be formed over the first p-i-n junction 126, a second TCO layer 122 may be formed over the second p-i-n junction 128, and a metal back layer 124 may be formed over the second TCO layer 122. To improve light absorption by enhancing light trapping, the substrate and/or one or more of thin films formed thereover may be optionally textured by wet, plasma, ion, and/or mechanical processes. For example, in the embodiment shown in FIG. 1, the first TCO layer 104 is textured so that the thin films subsequently deposited thereover will generally reproduce the topography of the surface below it.

The first TCO layer 104 and the second TCO layer 122 may each comprise tin oxide, zinc oxide, indium tin oxide, cadmium stannate, combinations thereof, or other suitable materials. It is understood that the TCO layer material may also include additional dopants and components. For example, zinc oxide may further include dopants, such as aluminum, gallium, boron, and other suitable dopants. Zinc oxide may comprise 5 atomic % or less of dopants, such as comprising about 2.5 atomic % or less aluminum. In certain instances, the substrate 102 may be provided by the glass manufacturers with the first TCO layer 104 already deposited thereon.

The first p-i-n junction 126 may comprise a p-type amorphous silicon layer 106, an intrinsic type amorphous silicon layer 108 formed over the p-type amorphous silicon layer 106, and an n-type microcrystalline silicon layer 110 formed over the intrinsic type amorphous silicon layer 108. In certain embodiments, the p-type amorphous silicon layer 106 may be formed to a thickness between about 60 Å and about 300 Å. In certain embodiments, the intrinsic type amorphous silicon layer 108 may be formed to a thickness between about 1,500 Å and about 3,500 Å. In certain embodiments, the n-type microcrystalline semiconductor layer 110 may be formed to a thickness between about 100 Å and about 400 Å.

The WSR layer 112 disposed between the first p-i-n junction 126 and the second p-i-n junction 128 is generally configured to have certain desired film properties. In one configuration, the WSR layer 112 actively serves as an intermediate reflector having a desired refractive index, or ranges of refractive indexes, to reflect light received from the light incident side of the solar cell 100. The WSR layer 112 also serves as a junction layer that boosts the absorption of the short to mid wavelengths of light (e.g., 280 nm to 800 nm) in the first p-i-n junction 126 and improves short-circuit current, resulting in improved quantum and conversion efficiency. The WSR layer 112 further has high film transmittance for mid to long wavelengths of light (e.g., 500 nm to 1100 nm) to facilitate the transmission of light to the layers formed in the junction 128. In one embodiment, the WSR layer 112 may be a microcrystalline silicon layer having n-type or p-type dopants disposed within the WSR layer 112. In an exemplary embodiment, the WSR layer 112 is an n-type crystalline silicon alloy having n-type dopants disposed within the WSR layer 112. Different dopants disposed within the WSR layer 112 may also influence optical and electrical properties, such as bandgap, crystalline fraction, conductivity, transparency, film refractive index, extinction coefficient, and the like. In some instances, one or more dopants may be doped into various regions of the WSR layer 112 to efficiently control and adjust the film bandgap, work function(s), conductivity, transparency and so on. In one embodiment, the WSR layer 112 is controlled to have a refractive index between about 1.4 and about 3, a bandgap of at least about 2 eV, and a conductivity greater than about 10⁻³ S/cm.

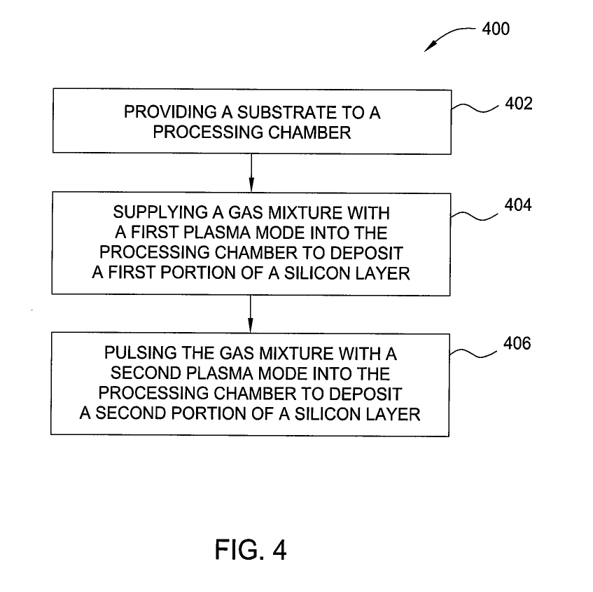

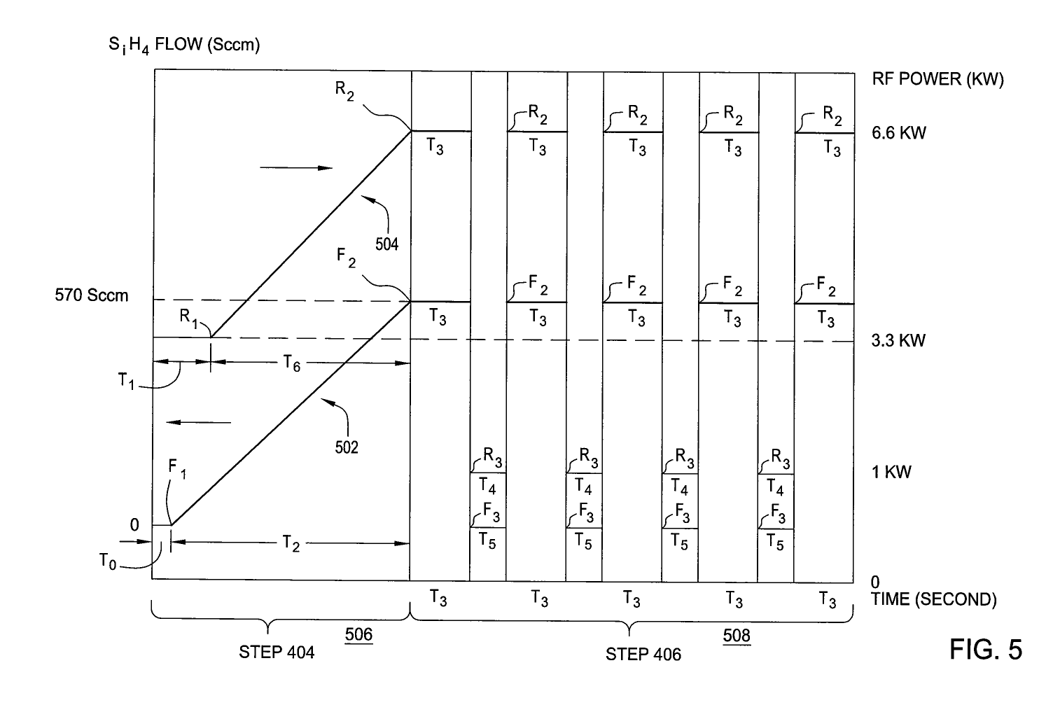

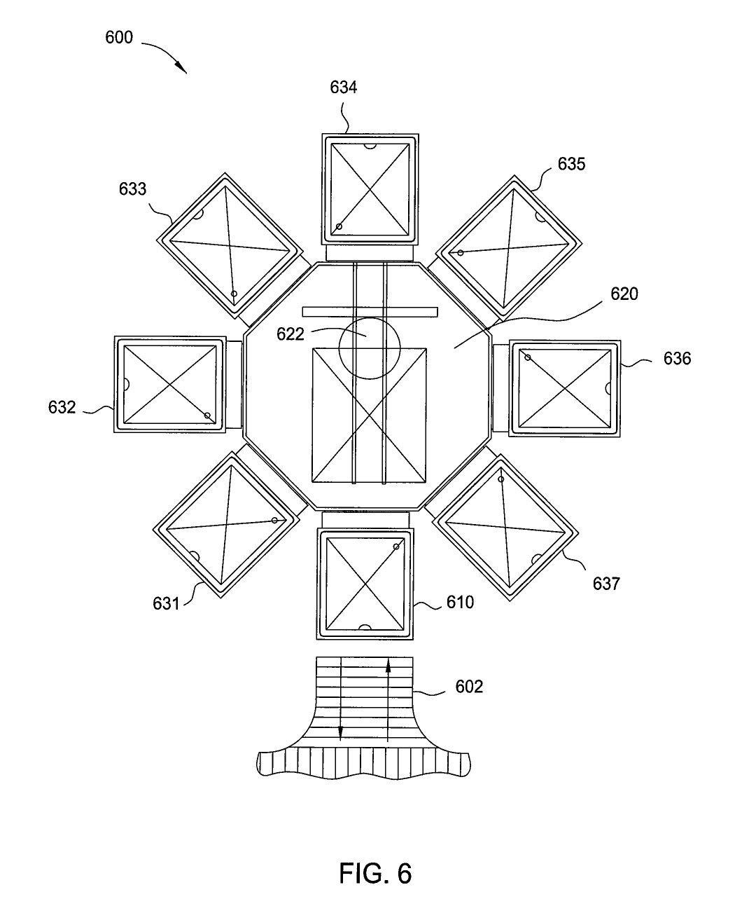

The second p-i-n junction 128 may comprise a p-type microcrystalline silicon layer 114, an intrinsic type microcrystalline silicon layer 118 formed over the p-type microcrystalline silicon layer 114, and an n-type amorphous silicon layer 120 formed over the intrinsic type microcrystalline silicon layer 118. In one embodiment, prior to the deposition of the bulk layer of the intrinsic type microcrystalline silicon layer 118, an intrinsic microcrystalline silicon seed layer 116 may be formed over the p-type microcrystalline silicon layer 114. In one embodiment, the seed layer 116 and the intrinsic type microcrystalline silicon layer 118 may be formed in a process by utilizing multiple process steps during deposition performed in a processing chamber. Alternatively, the seed layer 116 and the bulk intrinsic type microcrystalline silicon layer 118 may be formed in as many chambers as needed. More details regarding how to deposit the seed layer 116 and the bulk intrinsic type microcrystalline silicon layer 118 will be further described below with referenced to FIGS. 4-5.

In one embodiment, the p-type microcrystalline silicon layer 114 may be formed to a thickness between about 100 Å and about 400 Å. In certain embodiments, the intrinsic microcrystalline silicon seed layer 116 may be formed to a thickness between about 50 Å and about 500 Å. In certain embodiments, the bulk intrinsic type microcrystalline silicon layer 118 may be formed to a thickness between about 10,000 Å and about 30,000 Å. In certain embodiments, the n-type amorphous silicon layer 120 may be formed to a thickness between about 100 Å and about 500 Å.

The metal back layer 124 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 124 to complete the solar cell device. The formed solar cells may be interconnected to form modules, which in turn can be connected to form arrays.

Solar radiation 101 is primarily absorbed by the intrinsic layers 108, 118 of the p-i-n junctions 126, 128 and is converted to electron-holes pairs. The electric field created between the p-type layer 106, 114 and the n-type layer 110, 120 that stretch across the intrinsic layer 108, 118 causes electrons to flow toward the n-type layers 110, 120 and holes to flow toward the p-type layers 106, 114 creating a current. The first p-i-n junction 126 comprises an intrinsic type amorphous silicon layer 108 and the second p-i-n junction 128 comprises an intrinsic type microcrystalline silicon layer 118 since amorphous silicon and microcrystalline silicon absorb different wavelengths of the solar radiation 101. Therefore, the formed solar cell 100 is more efficient, since it captures a larger portion of the solar radiation spectrum. The intrinsic layer 108, 118 of amorphous silicon and the intrinsic layer of microcrystalline are stacked so that solar radiation 101 first strikes the intrinsic type amorphous silicon layer 118 and transmitted through the WSR layer 112 and then strikes the intrinsic type microcrystalline silicon layer 118 since amorphous silicon has a larger bandgap than microcrystalline silicon. Solar radiation not absorbed by the first p-i-n junction 126 continuously transmits through the WSR layer 112 and continues on to the second p-i-n junction 128.

Charge collection is generally provided by doped semiconductor layers, such as silicon layers doped with p-type or n-type dopants. P-type dopants are generally group III elements, such as boron or aluminum. N-type dopants are generally group V elements, such as phosphorus, arsenic, or antimony. In most embodiments, boron is used as the p-type dopant and phosphorus as the n-type dopant. These dopants may be added to the p-type and n-type layers 106, 110, 114, 120 described above by including boron-containing or phosphorus-containing compounds in the reaction mixture. Suitable boron and phosphorus compounds generally comprise substituted and unsubstituted lower borane and phosphine oligomers. Some suitable boron compounds include trimethylboron (B(CH₃)₃ or TMB), diborane (B₂H₆), boron trifluoride (BF₃), and triethylboron (B(C₂H₅)₃ or TEB). Phosphine is a common phosphorus compound. The dopants are generally provided with carrier gases, such as hydrogen, helium, argon, and other suitable gases. If hydrogen is used as the carrier gas, the total hydrogen in the reaction mixture will be increased. Thus hydrogen ratios will include hydrogen used as a carrier gas for dopants.

Dopants will generally be provided as dilute gas mixtures in an inert gas. For example, dopants may be provided at molar or volume concentrations of about 0.5% in a carrier gas. If a dopant is provided at a volume concentration of 0.5% in a carrier gas flowing at 1.0 sccm/L, the resultant dopant flow rate will be 0.005 sccm/L. Dopants may be provided to a reaction chamber at flow rates between about 0.0002 sccm/L and about 0.1 sccm/L depending on the degree of doping desired. In general, dopant concentration is maintained between about 10¹⁸ atoms/cm² and about 10²⁰ atoms/cm².

In one embodiment, the p-type microcrystalline silicon layer 114 may be deposited by providing a gas mixture of hydrogen gas and silane gas in ratio of hydrogen-to-silane of about 200:1 or greater, such as 1000:1 or less, for example between about 250:1 and about 800:1, and in a further example about 601:1 or about 401:1. Silane gas may be provided at a flow rate between about 0.1 sccm/L and about 0.8 sccm/L, such as between about 0.2 sccm/L and about 0.38 sccm/L. Hydrogen gas may be provided at a flow rate between about 60 sccm/L and about 500 sccm/L, such as about 143 sccm/L. TMB may be provided at a flow rate between about 0.0002 sccm/L and about 0.0016 sccm/L, such as about 0.00115 sccm/L. If TMB is provided in a 0.5% molar or volume concentration in a carrier gas, then the dopant/carrier gas mixture may be provided at a flow rate between about 0.04 sccm/L and about 0.32 sccm/L, such as about 0.23 sccm/L. RF power may be applied between about 50 mW/cm² and about 700 mW/cm², such as between about 290 mW/cm² and about 440 mW/cm². Chamber pressure may be maintained between about 1 Torr and about 100 Torr, such as between about 3 Torr and about 20 Torr, for example between 4 Torr and about 12 Torr, such as about 7 Torr or about 9 Torr. These conditions will deposit a p-type microcrystalline layer having crystalline fraction between about 20 percent and about 80 percent, such as between 50 percent and about 70 percent at a rate of about 10 Å/min or more, such as about 143 Å/min or more.

In one embodiment, a second dopant, such as carbon, germanium, nitrogen, oxygen, in the p-type microcrystalline silicon layer 114 may improve photoelectronic conversion efficiency. Details regarding how a second dopant can improve the overall solar cell performance is disclosed in detail by U.S. patent application Ser. No. 12/208,478, filed Sep. 11, 2008 with the title “Microcrystalline Silicon Alloys for Thin Film and Wafer Based Solar Applications” which is herein incorporated by reference

In one embodiment, the p-type amorphous silicon layer 106 may be deposited by providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. RF power may be applied between about 15 mWatts/cm² and about 200 mWatts/cm². Chamber pressure may be maintained between about 0.1 Torr and 20 Torr, such as between about 1 Torr and about 4 Torr, to deposit a p-type amorphous silicon layer at about 100 Å/min or more from the gas mixture.

In one embodiment, the n-type microcrystalline silicon layer 110 may be deposited by providing a gas mixture of hydrogen gas to silane gas in a ratio (by volume) of about 100:1 or more, such as about 500:1 or less, such as between about 150:1 and about 400:1, for example about 304:1 or about 203:1. Silane gas may be provided at a flow rate between about 0.1 sccm/L and about 0.8 sccm/L, such as between about 0.32 sccm/L and about 0.45 sccm/L, for example about 0.35 sccm/L. Hydrogen gas may be provided at a flow rate between about 30 sccm/L and about 250 sccm/L, such as between about 68 sccm/L and about 143 sccm/L, for example about 71.43 sccm/L. Phosphine may be provided at a flow rate between about 0.0005 sccm/L and about 0.006 sccm/L, such as between about 0.0025 sccm/L and about 0.015 sccm/L, for example about 0.005 sccm/L. In other words, if phosphine is provided in a 0.5% molar or volume concentration in a carrier gas, then the dopant/carrier gas may be provided at a flow rate between about 0.1 sccm/L and about 5 sccm/L, such as between about 0.5 sccm/L and about 3 sccm/L, for example between about 0.9 sccm/L and about 1.088 sccm/L. RF power may be applied between about 100 mW/cm² and about 900 mW/cm², such as about 370 mW/cm². Chamber pressure may be maintained between about 1 Torr and about 100 Torr, such as between about 3 Torr and about 20 Torr, for example between 4 Torr and about 12 Torr, for example about 6 Torr or about 9 Torr, to deposit an n-type microcrystalline silicon layer having a crystalline fraction between about 20 percent and about 80 percent, for example between 50 percent and about 70 percent, at a rate of about 50 Å/min or more, such as about 150 Å/min or more.

In one embodiment, the n-type amorphous silicon layer 120 may be deposited by providing a gas mixture of hydrogen gas to silane gas in a ratio (by volume) of about 20:1 or less, such as about 5:5:1 or 7.8:1. Silane gas may be provided at a flow rate between about 0.1 sccm/L and about 10 sccm/L, such as between about 1 sccm/L and about 10 sccm/L, between about 0.1 sccm/L and 5 sccm/L, or between about 0.5 sccm/L and about 3 sccm/L, for example about 1.42 sccm/L or 5.5 sccm/L. Hydrogen gas may be provided at a flow rate between about 1 sccm/L and about 40 sccm/L, such as between about 4 sccm/L and about 40 sccm/L, or between about 1 sccm/L and about 10 sccm/L, for example about 6.42 sccm/L or 27 sccm/L. Phosphine may be provided at a flow rate between about 0.0005 sccm/L and about 0.075 sccm/L, such as between about 0.0005 sccm/L and about 0.0015 sccm/L or between about 0.015 sccm/L and about 0.03 sccm/L, for example about 0.0095 sccm/L or 0.023 sccm/L. If phosphine is provided in a 0.5% molar or volume concentration in a carrier gas, then the dopant/carrier gas mixture may be provided at a flow rate between about 0.1 sccm/L and about 15 sccm/L, such as between about 0.1 sccm/L and about 3 sccm/L, between about 2 sccm/L and about 15 sccm/L, or between about 3 sccm/L and about 6 sccm/L, for example about 1.9 sccm/L or about 4.71 sccm/L. RF power may be applied between about 25 mW/cm² and about 250 mW/cm², such as about 60 mW/cm² or about 80 mW/cm². Chamber pressure between about 0.1 Torr and about 20 Torr, such as between about 0.5 Torr and about 4 Torr, such as about 1.5 Torr, will deposit an n-type amorphous silicon layer at a rate of about 100 Å/min or more, such as about 200 Å/min or more, such as about 300 Å/min or about 600 Å/min.

In some embodiments, the silicon layers may be heavily doped or degenerately doped by supplying dopant compounds at high rates, for example at rates in the upper part of the recipes described above. It is thought that degenerate doping improves charge collection by providing low-resistance contact junctions. Degenerate doping is also thought to improve conductivity of some layers, such as amorphous layers.

In one embodiment, the intrinsic amorphous silicon layer 108 may be deposited by providing a gas mixture of hydrogen gas to silane gas in a ratio (by volume) of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between 15 mW/cm² and about 250 mW/cm² may be provided to the showerhead. The pressure of the chamber may be maintained between about 0.1 Torr and 20 Torr, such as between about 0.5 Torr and about 5 Torr. The deposition rate of the intrinsic type amorphous silicon layer 108 may be about 100 Å/min or more. In an exemplary embodiment, the intrinsic type amorphous silicon layer 108 is deposited at a hydrogen to silane ratio of about 12.5:1.

Further details regarding deposition of the intrinsic type microcrystalline silicon seed layer 116 and the intrinsic type microcrystalline silicon layer 118 will be further described below with referenced to FIGS. 4-5.

FIG. 2 is a schematic diagram of an embodiment of a single junction solar cell 200 having the intrinsic type microcrystalline silicon seed layer 116 and the intrinsic type microcrystalline silicon layer 118. Solar cell 200 comprises the substrate 102, the first transparent conducting oxide (TCO) layer 104 formed over the substrate 102, a single p-i-n junction 206 formed over the first TCO layer 104. The second TCO layer 122 is formed over the single p-i-n junction 206, and a metal back layer 124 formed over the second TCO layer 122. In one embodiment, the single p-i-n junction 206 includes a p-type silicon layer 202, the intrinsic type microcrystalline silicon seed layer 116 and the intrinsic type microcrystalline silicon layer 118, and a n-type silicon layer 208 formed over the intrinsic type microcrystalline silicon layer 118. The p-type 202 and the n-type silicon layer 208 may be any types of silicon layers, including amorphous silicon, microcrystalline silicon, polysilicon, and so on, utilized to form the p-i-n junction 206. The detail description regarding how the intrinsic type microcrystalline silicon seed layer 116 and the intrinsic type microcrystalline silicon layer 118 may be formed will be further discussed below with referenced to FIGS. 4-5.

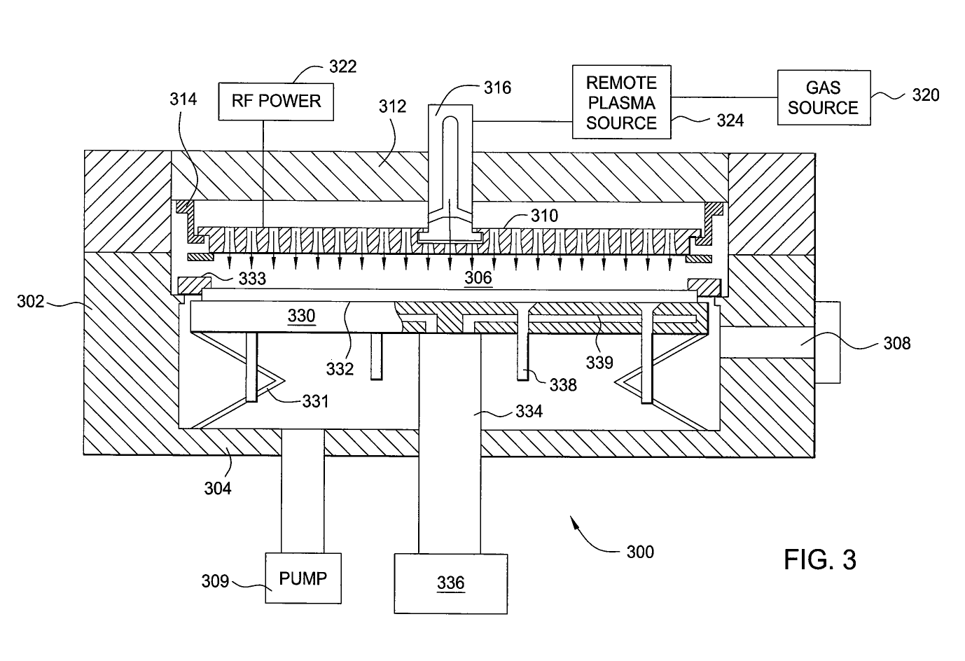

FIG. 3 is a schematic cross-section view of one embodiment of a plasma enhanced chemical vapor deposition (PECVD) chamber 300 in which the intrinsic type microcrystalline silicon seed layer 116 and the intrinsic type microcrystalline silicon layer 118 as described in FIG. 1 and 2 may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 300 generally includes walls 302, a bottom 304, and a showerhead 310, and substrate support 330 which define a process volume 306. The process volume is accessed through a valve 308 such that the substrate may be transferred in and out of the chamber 300. The substrate support 330 includes a substrate receiving surface 332 for supporting a substrate and stem 334 coupled to a lift system 336 to raise and lower the substrate support 330. A shadow ring 333 may be optionally placed over periphery of the substrate 102. Lift pins 338 are moveably disposed through the substrate support 330 and may be actuated to space the substrate from the substrate receiving surface 332 to facilitate robotic transfer. The substrate support 330 may also include heating and/or cooling elements 339 to maintain the substrate support 330 at a desired temperature. The substrate support 330 may also include RF conductive straps 331 to provide an RF return path at the periphery of the substrate support 330.

The showerhead 310 is coupled to a backing plate 312 at its periphery by a suspension 314. The showerhead 310 may also be coupled to the backing plate by one or more center supports 316 to help prevent sag and/or control the straightness/curvature of the showerhead 310. A gas source 320 is coupled to the backing plate 312 to provide gas through the backing plate 312 and through the showerhead 310 to the substrate receiving surface 332. A vacuum pump 309 is coupled to the chamber 300 to control the process volume 306 at a desired pressure. An RF power source 322 is coupled to the backing plate 312 and/or to the showerhead 310 to provide a RF power to the showerhead 310. The RF power creates an electric field between the showerhead and the substrate support 330 so that a plasma may be generated from the gases between the showerhead 310 and the substrate support 330. Various RF frequencies may be used, such as a frequency between about 0.3 MHz and about 200 MHz. In one embodiment the RF power source is provided at a frequency of 13.56 MHz.

A remote plasma source 324, such as an inductively coupled remote plasma source, may also be coupled between the gas source and the backing plate. Between processing substrates, a cleaning gas may be provided to the remote plasma source 324 which generates a remote plasma that is provided to clean chamber components in the process volume 306. The cleaning gas may be further excited by the RF power source 322 provided to the showerhead. Suitable cleaning gases include but are not limited to NF₃, F₂, and SF₆.

The deposition methods for intrinsic type microcrystalline silicon layers, such as microcrystalline silicon layers 116, 118 of FIGS. 1-2, may include the following deposition parameters in the process chamber of FIG. 3 or other suitable chamber. A substrate having a surface area of 10,000 cm² or more, for example 40,000 cm² or more, and such as 55,000 cm² or more is provided to the chamber. It is understood that after processing the substrate may be cut to form smaller solar cells.

In one embodiment, the heating and/or cooling elements 339 may be set to provide a substrate support temperature during deposition of about 400° C. or less, such as between about 100° C. and about 400° C., for example between about 150° C. and about 300° C., such as about 200° C. The spacing during deposition between the top surface of a substrate disposed on the substrate receiving surface 332 and the showerhead 310 may be between 400 mil and about 1,200 mil, such as between 400 mil and about 800 mil.

FIG. 4 depicts a process flow of a method 400 for depositing an intrinsic type microcrystalline silicon layer, such as the intrinsic type microcrystalline silicon seed layer 116 and the intrinsic type microcrystalline silicon layer 118. The method 400 may be performed in a plasma chamber, such as the plasma chamber 300 depicted in FIG. 3. It is noted that the method 400 may be performed in any suitable plasma chamber, including those from other manufacturers.

The method 400 begins at step 402 by providing a substrate, such as the substrate 102 depicted in FIGS. 1-2, into the processing chamber. The substrate 102 may have the first TCO layer 104 and the p-type silicon layer 202 disposed thereon, as depicted in the embodiment of FIG. 2. The p-type silicon layer may be an amorphous silicon layer, a microcrystalline silicon layer, a polysilicon layer, or any other suitable silicon containing layers. Alternatively, the substrate 102 may have the first TCO layer 104, the first p-i-n junction 126, optionally the WSR layer 112, and the p-type microcrystalline silicon layer 114, as depicted in the embodiment of FIG. 1. It is noted that the substrate 102 may have different combination of films, structures or layers previously formed thereon to facilitate forming the intrinsic type microcrystalline silicon layer on the substrate 102 to form solar cells. In one embodiment, the substrate 102 may be any one of a glass substrate, a plastic substrate, a polymer substrate, or other transparent substrate suitable for forming solar cells thereon.

At step 404, a gas mixture is supplied into the processing chamber to deposit the intrinsic type microcrystalline silicon seed layer 116. During depositing, the RF power applied to ignite the plasma in the gas mixture may be controlled at a first mode to facilitate depositing the seed layer 116 with desired film properties. In one embodiment, the gas mixture may include a silicon-based gas and a hydrogen based gas. Suitable silicon based gases include, but are not limited to, silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to, hydrogen gas (H₂). In one embodiment, the silicon based gas described herein is silane (SiH₄) and the hydrogen-based gas described herein is hydrogen (H₂).

In one embodiment, the silicon based gases, such as the silane gas, supplied in the gas mixture may be gradually ramped up from a first predetermined set point to a second predetermined set point during a first process period. For example, as an exemplary embodiment depicted in FIG. 5, the silane gas flow, as depicted by trace line 502, in the gas mixture may be gradually ramped up from a first predetermined set point F₁ to a predetermined set point F₂ at a predetermined time period T₂ at a first process period 506 performed at step 404. It is noted that the term “ramp up” used herein means gradually tuning up a process parameter from a first set point to a second set point at a predetermined time period with a desired ramp-up rate. The term “ramp up” used herein is not a sudden change caused by an action of throttle valve open or close.

In one embodiment, the first and the second predetermined set points F₁, F₂ of the silane gas flow may be varied according to different requirements for the film quality. For example, in an embodiment wherein the seed layer 116 is required to be formed as a highly porous and hydrogen-rich layer so as to provide nucleation sites for the subsequent Si atoms to nucleate thereon, a low-to-high silane gas flow ramping may be used. Alternatively, the silane gas flow supplied in the gas mixture may be varied or controlled as needed.

It is believed that the gradually ramp-up of the silane gas flow in the gas mixture may assist silicon atoms to uniformly adhere and distribute on the substrate surface, thereby forming the seed layer 116 with desirable film properties. Uniform adherence of the silicon atoms on the substrate surface provides good nucleation sites for the subsequent atoms to nucleate thereon. Uniform nucleation sites formed on the substrate promotes crystallinity of the films subsequently formed thereon. Therefore, the gradually ramp-up of the silane flow in the gas mixture allows the dissociated silicon atoms from the gas mixture to have sufficient time to be gradually absorbed on the substrate surface, thereby providing a surface having an even distribution of silicon atoms that provides nucleation sites which promote improved crystallinity of the subsequent deposited layers.

In one embodiment, the silane gas flow supplied at step 404 during the first process period 506 is supplied from the first set point F₁, such as zero, to the second set point F₂, such as between about 2.8 sccm/L and about 5.6 sccm/L, for example about 3.99 sccm/L (about 570 sccm). The predetermined time period T₂ for silane flow to ramp up is between about 20 seconds to about 300 seconds, such as between about 40 seconds and about 240 seconds, such as between about 60 seconds and about 120 seconds. Although the embodiment depicted in FIG. 5 indicates that the silane gas flow trace line 502 gradually ramps up linearly, it is noted that the silane gas flow may be supplied using other ramping profiles, such as parabolic, reverse-parabolic, or curved, or any other suitable profile, until a desired gas flow rate of silane flow is reached.

In one embodiment, the silane gas and the hydrogen gas may be supplied into the processing chamber at a predetermined gas flow ratio. The predetermined gas flow ratio of hydrogen to silane gas assists the microcrystalline silicon seed layer 116 to be formed with a desired crystalline fraction and grain structure. In one embodiment, the hydrogen to silane gas flow ratio (e.g., flow volume ratio) in the gas mixture is controlled between about 20:1 and about 200:1, or between about 30:1 and about 150:1, such as about 50:1. In one particular embodiment, the hydrogen gas supplied in the gas mixture may be provided at a steady rate while the silane gas flow is gradually ramped up until a desired ratio of the silane gas to the hydrogen gas is reached. For example, if the target second silane flow F₂ is set about 3.99 sccm/L, as depicted in FIG. 5, and the ratio of the hydrogen to silane gas flow is set at 50:1, the hydrogen gas may be supplied at about 199.5 sccm/L (e.g., 3.99 sccm/L×50=199.5 sccm/L) at the beginning of the first process period T₀ to the end of the first process time period 506. In contrast, the silane gas flow is gradually supplied and ramped up from zero F₁ to the target silane flow F₂ of 3.99 sccm/L at the predetermined time period T₂. It is believed that the low silane flow rate in the initial stage of the deposition may assist formation of film crystalline and nucleation sites due to the relatively pure hydrogen plasma environment and/or high hydrogen dilution in the gas mixture. Alternatively, the hydrogen flow may start with a relatively flow rate and then gradually ramped down, similar to the manner for ramping up the silane flow, until the desired ratio of the hydrogen to silane gas flow is reached.

During depositing at step 404, the RF power applied to ignite the plasma in gas mixture may be controlled in a manner that can plasma ionize the gas mixture in a desired manner. For example, as the silane flow supplied in the gas mixture is gradually ramped up, the RF power applied to the processing chamber is also configured to be gradually ramped up to prevent overly exciting or dissociating the gas species supplied in the gas mixture at the initial stage of the process. Providing an overly high amount of RF power at the initial stage of the deposition may result in high ion bombardment, which may damage the underlying layers, produce arcing on the substrate surface and the chamber hardware components, and contribute to a non-uniform or overly excited state of the ions formed in the gas mixture, which may result in non-uniform distribution of the atoms on the substrate surface. In order to prevent such occurrences, the RF power is gradually ramped up to prevent ions from being dissociated in an overly excited or unstable state.

In one embodiment, as depicted in FIG. 5, in the early stage of the process step 404, the RF power, as shown by the RF trace line 504, is applied at a first lower set point R₁ during a first time period T₁. After the gas mixture, such as the silane gas shown in trace line 502, is supplied to the processing chamber, the RF power then gradually ramped up from the first lower set point R₁ to a second higher set point R₂ at the second time period T₆. In other words, the RF power ramps up to the second set point R₂ has a time delay T₁ as compared to the time point T₀ when the gas mixture is supplied into the processing chamber. The time period of T₁ is controlled to be longer than the time period of T₀ so that ramping of the RF power lags behind supply of the gas mixture into the processing chamber. In one embodiment, the T₁ period may be controlled between about 0.1 seconds and about 240 seconds, such as between about 5 seconds and about 80 seconds, for example about 30 seconds. After the predetermined time period T₁ is lapsed, the RF power may then be applied to ignite the plasma in the gas mixture.

Similar to the manner used to control the silane flow at step 404, the RF power applied to the processing chamber may be ramped up from the first set point R₁ to the second set point R₂ during the predetermined time period T₆, as depicted in FIG. 5. In one embodiment, the first lower set point R₁ of the RF power is controlled between about 0 Watts and about 5 KiloWatts. If the power unit is represented by power density, the RF power density may be controlled at between about 0 Watts/cm₂ and about 1.2 Watts/cm₂. The second higher set point R₂ of the RF power is controlled between about 2 KiloWatts and about 8 KiloWatts, such as between about 4 KiloWatts and about 7 KiloWatts, for example about 6.6 KiloWatts. If the power unit is represented by power density, the RF power density may be controlled between about 0.46 Watts/cm₂ and about 2 Watts/cm₂, such as between about 0.92 Watts/cm₂ and about 1.61 Watts/cm₂, for example between about 1.52 Watts/cm₂. Similar to the manner utilized to control silane flow 502, the RF power as applied to the processing chamber may by gradually ramped up in a linear, parabolic, reverse- parabolic, or curved, or any other suitable profiles, until the second set point R₂ of RF power is reached, as discussed above.

In one embodiment, the total process time 506 of the step 404 is controlled to deposit the seed layer 116 in a desired thickness range. In one embodiment, the thickness of the seed layer 116 is controlled at between about 50 Å and about 500 Å. Furthermore, the total process time 506 for RF power and the silane gas flow to be ramped up to the desired target value R₂, F₂ is controlled at a similar time frame. For example, the total time length of the RF ramp-up time (T₁+T₆) is controlled to be similar to the total time length of the silane ramp-up time (T₀+T₂). During the predetermined first time period 506, the total time period for RF ramp-up time (T₁+T₆) and silane ramp-up time (T₀+T₂) is controlled to be between about 20 seconds and about 300 seconds. In other words, toward the end of the first time period 506, the RF power and the silane flow in the gas mixture will be applied and supplied in the processing chamber close to the desired second set points, R₂ and F₂, so that the RF power and the silane flow can be maintained in a steady state while entering into the next process step and process time period.

During step 404, several process parameters may be controlled during deposition process. The RF power may be provided to the processing chamber at a frequency between about 100 kHz and about 100 MHz, such as about 350 kHz or about 13.56 MHz. Alternatively, a VHF power may be utilized to provide a frequency up to between about 27 MHz and about 200 MHz. The spacing of the substrate to the gas distribution plate assembly may be controlled in accordance with the substrate dimension. In one embodiment, the spacing for a substrate greater than 1 square meters is controlled between about 400 mils and about 1200 mils, for example, between about 400 mils and about 850 mils, such as 550 mils. The process pressure may be controlled between about 1 Torr and about 12 Torr, such as between about 3 Torr and about 10 Torr, for example about 9 Torr. The substrate temperature may be controlled between about 50 degrees Celsius and about 300 degrees Celsius, such as between about 100 degrees Celsius and about 250 degrees Celsius, for example about 200 degrees Celsius.

At step 406, after the RF power 504 and the silane flow 502 supplied to the processing chamber have reached to the predetermined set points R₂, F₂, the manner in which the gas mixture and the RF power supplied and applied into the processing chamber is varied using a second mode to deposit the bulk intrinsic type microcrystalline silicon layer 118 over the seed layer 116. Instead of continuously supplying RF power and gas mixture into the processing chamber, the RF power and the gas mixture in the second process time period 508 at step 406 are pulsed. In the exemplary embodiment depicted in FIG. 5, as the set points R₂, F₂ are reached after the first process period 506, the supply of RF power 504 and the silane gas flow 502 is alternated to pulse the RF power and silane gas flow into the processing chamber over different time periods defined in the second process period 508. The length of the second process period 508 may be controlled to deposit a desired thickness of the intrinsic type microcrystalline silicon layer 118 is reached. For example, the total second process period 508 may be controlled between about 300 seconds to about 3600 seconds, such as about 600 seconds and about 1800 seconds to form the intrinsic type microcrystalline silicon layer 118 having a thickness between about 10000 Å and about 30000 Å.

In one embodiment, when entering into the second process time period 508, the RF power and the gas flow rate may be maintained at about the same level as the set points R₂, F₂ at step 404. After the silane flow 502 is supplied at the flow rate F₂ for a predetermined time period T₃, the silane flow 502 may be pulsed and turned down to a third flow rate F₃ for another predetermined time period T₅. In one embodiment, the flow rate F₃ is controlled at between about 0 sccm/L and about 1.42 sccm/L. In the embodiment wherein flow rate F₃ is controlled at zero, the silane gas flow 502 is substantially turned off. Subsequently, the silane flow 502 may be maintained in an “on-off” pulsed mode until the predetermined process time period 508 is reached.

Similar to the arrangement for supplying the silane flow, after the process has entered into the second process time period 508, the RF power applied to ignite the plasma may be set to a pulsed mode, intermittently applying RF power over different time spans during the second process time period 508. As depicted in FIG. 5, after the RF power 504 is applied at the set point R₂ for a predetermined time period T₃, the RF power 504 may be pulsed and applied at a different power range R₃ for another predetermined time period T₄. Subsequently, the RF power 504 may maintain in the pulsed mode and intermittently applied into the processing chamber until the predetermined process time period 508 is expired. In one embodiment, the RF power 504 may be supplied from a first power for the first time period T₃ and pulsed/lowered to a second power for the second time period T₄. In one embodiment, the RF power 504 may be supplied from the first range R₂ between about 4 KiloWatts and about 7 KiloWatts, for example about 6.6 KiloWatts, and lowered down the second range R₃ to between about 0 KiloWatts and about 2 KiloWatts, for example about 1 KiloWatts.

In one embodiment, the RF power range and the gas flow rate may be pulsed synchronously lagged, or alternatively to maintain a desired processing condition of the processing chamber. It is believed that utilizing pulse mode for applying RF power to produce plasma in the gas mixture may reduce likelihood of arcing during processing. Pulse RF power mode may also prevent overheat of the substrate during processing, which may adversely result in low film quality and electrical properties. Additionally, pulse RF power mode may give the option for higher voltage and peak power during processing while keeping an average power at a lower range, thereby efficiently improving the deposition rate without causing overly high ion bombardment to the substrate surface. In conventional practices, it is believed that high deposition rate can only be obtained with a large gas mixture flow rate, high RF power range, and high ratio of hydrogen to silane gas. However, high gas mixture flow rate and high ratio of hydrogen to silane gas may result in high gas consumption and high manufacture cost, and the high RF power may increase likelihood of substrate damage. Here, by modulating the pulsed mode of the RF power and gas mixture supplied to the processing chamber, it is surprisingly found that the RF power required to supply to the processing chamber is reduced about 20 percent to about 50 percent during processing while maintaining similar desired high deposition rate as compared to using conventional continuous RF power supply. Furthermore, consumption of the silane gas flow rate may also be saved by about 30 to 40 percent. The ratio of the hydrogen to silane may also be lowered to save gas consumption by about 15 percent and 20 percent gas while maintaining the desired high deposition rate and high film crystalline. Accordingly, by efficiently controlling a desired amount of gas flow rate as well as the pulsed mode of RF power and gas mixture, the overly high ion bombardment, unstable electron temperature, plasma overheating may be substantially reduced and/or eliminated, thereby providing a plasma environment that beneficially assists forming the intrinsic microcrystalline silicon layer 118 with high film crystalline fraction and crystalline uniformity. In one embodiment, deposition rate of the process controlled at step 406 may be between about 700 Å per minute and about 1500 Å per minute, such as between about 800 Å per minute and about 1200 Å per minute, for example about 1000 Å per minute.

In one embodiment, as the exemplary embodiment depicted in the FIG. 5, the silane flow 502 and the RF power 504 may be simultaneously applied to the processing process at the beginning of the step 406 for the first time period T₃. In one embodiment, the first time period T₃ is between about 10 seconds and about 150 seconds, such as between about 20 seconds and about 120 seconds, for example about 90 seconds. Subsequently, the silane flow 502 and the RF power 504 may be substantially turned off or lowered to the second range F₃, R₃ for the second time period T₄ and T₅. In one embodiment, the second time period T₄ and T₅ is between about 0.1 seconds and about 60 seconds, such as between about 5 seconds and about 30 seconds, for example about 10 seconds. It is noted the time period of T₄ and T₅ may be the same or different as needed. Accordingly, the silane gas flow and the RF power may be pulsed every 0.1 seconds to about 60 seconds (e.g., time period of T₄ and T₅) for about between about 10 seconds and about 150 seconds (e.g., time period of T₃). In between each pulse (e.g., time period of T₄ and T₅), hydrogen gas or other purge gas, such as Ar or He, may be supplied into the processing chamber to maintain the pressure within the processing chamber.

In one embodiment, during depositing at step 406, the hydrogen gas flow rate may be maintained at substantially the same the flow rate as supplied at step 404. In another embodiment, the hydrogen flow rate may be between about 80 sccm/L and about 400 sccm/L at step 406. In yet another embodiment, the hydrogen flow rate may be supplied in the pulsed mode similar to the manner used to supply RF power and silane flow during the second processing period. In one embodiment, the flow rate of hydrogen gas and silane gas are synchronously pulsed at every about 0.1 seconds to about 60 seconds into the processing chamber.

In one embodiment, inert gas or carrier gas, such as He, and Ar, may also be supplied to the processing chamber as needed. Furthermore, if one or more dopants are desired to be formed in the resultant intrinsic type microcrystalline silicon layer, one or more dopant gases, such as CO₂, O₂, N₂O, NO₂, CH₄, CO, H₂, Ge containing precursor, N₂, and the like, are provided to form a silicon alloy microcrystalline silicon layer as needed.

In one embodiment, the cycle of the RF power and silane gas flow pulsed into the processing chamber may be repeated as many times as needed until the total second processing time period 508 is reached. In one embodiment, the cycle of the RF power and silane gas flow pulsed into the processing chamber may be repeated for between about 1 times and about 20 times, such as about 3 times and about 8 times, such as about 5 times. Alternatively, the cycle of the RF power and silane gas flow pulsed into the processing chamber may be repeated as many times as needed until a desired thickness of the intrinsic type microcrystalline silicon layer 118 has been reached. In one embodiment, the intrinsic type microcrystalline silicon layer 118 has a thickness between about 5000 Å and about 50000 Å, such as about 10000 Å and about 30000 Å, for example about 20000 Å.

By efficiently controlling the flow rate of the gas mixture and the RF power supplied into the processing chamber in pulsed modes, a desired process condition may be obtained. Furthermore, by efficiently adjusting the flow rate/ratio in the gas mixture, RF power range, and supplying mode during the first processing time 506 and the second processing time 508, a desired film property, such as high crystalline fraction and film crystalline uniformity, may be deposited across the substrate. As discussed above, as the silane flow rate at the initial stage of step 404 is controlled at a relatively low gas flow rate, a high film crystalline fraction may be obtained in the intrinsic type microcrystalline silicon seed layer 116, as compared to bulk intrinsic type microcrystalline silicon layer 118. High initial film crystalline fraction in the intrinsic type microcrystalline silicon seed layer 116 may assist the following bulk intrinsic type microcrystalline silicon layer deposited thereon to maintain good crystalline fraction. As the deposition at step 404 provides a good nucleation surface on the substrate surface, the subsequent material deposited at step 406 can follow the crystalline plane defined in the seed layer 116, thereby allowing the following layers to grow thereon with a good crystalline fraction and uniformity. In one embodiment, the resultant intrinsic type microcrystalline silicon layer may have a crystalline fraction greater than 60 percent. As the film crystalline fraction and film crystalline uniformity improve, the photoelectric conversion efficiency may be improve about 50 percent to about 150 percent, resulting in significant increase in the device performance of the PV solar cell.

FIG. 6 is a top schematic view of one embodiment of a process system 600 having a plurality of process chambers 631-637, such as PECVD chamber 300 of FIG. 3 or other suitable chambers capable of depositing silicon films. The process system 600 includes a transfer chamber 620 coupled to a load lock chamber 610 and the process chambers 631-637. The load lock chamber 610 allows substrates to be transferred between the ambient environment outside the system and vacuum environment within the transfer chamber 620 and process chambers 631-637. The load lock chamber 610 includes one or more evacuatable regions holding one or more substrate. The evacuatable regions are pumped to facilitate insertion of substrates into the system 800 and are vented to facilitate removal of the substrates from the system 600. The transfer chamber 620 has at least one vacuum robot 622 disposed therein that is adapted to transfer substrates between the load lock chamber 810 and the process chambers 631-637. While seven process chambers are shown in FIG. 6; this configuration is not intended to be limiting as to the scope of the invention, since the system may have any suitable number of process chambers.

In certain embodiments of the invention, the system 600 is configured to deposit the first p-i-n junction 126, such as shown in FIG. 1, of a multi-junction solar cell. In one embodiment, one of the process chambers 631-637 is configured to deposit the p-type layer(s) of the first p-i-n junction while the remaining process chambers 631-637 are each configured to deposit both the intrinsic type layer(s) and the n-type layer(s). The intrinsic type layer(s) and the n-type layer(s) of the first p-i-n junction may be deposited in the same chamber without any passivation processes performed between the deposition steps. Thus, in one embodiment, a substrate enters the system through the load lock chamber 610, the substrate is then transferred by the vacuum robot into the dedicated process chamber configured to deposit the p-type layer(s). Next, after forming the p-type layer the substrate is transferred by the vacuum robot into one of the remaining process chamber configured to deposit both the intrinsic type layer(s) and the n-type layer(s). After forming the intrinsic type layer(s), and the n-type layer(s) the substrate is transferred by the vacuum robot 622 back to the load lock chamber 610. In certain embodiments, the time to process a substrate in the process chamber to form the p-type layer(s) is approximately 4 or more times faster, such as 6 or more times faster, than the time to form the intrinsic type layer(s) and the n-type layer(s) in a single chamber. Therefore, in certain embodiments of the system, the ratio of p-chambers to i/n-chambers is 1:4 or more, such as 1:6 or more. The throughput of the system including the time to provide plasma cleaning of the process chambers may be about 10 substrates/hr or more, for example 20 substrates/hr or more.

In certain embodiments of the invention, a system 600 may be configured to deposit the second p-i-n junction 128 such as shown in FIG. 1 of a multi-junction solar cell. In one embodiment, one of the process chambers 631-637 is configured to deposit the p-type layer(s) of the second p-i-n junction while the remaining process chambers 631-637 are each configured to deposit both the intrinsic type layer(s) and the n-type layer(s). The intrinsic type layer(s) and the n-type layer(s) of the second p-i-n junction may be deposited in the same chamber without any passivation process performed in between the deposition steps. In certain embodiments, the time to process a substrate within the process chamber to form the p-type layer(s) may be approximately 4 or more times faster than the time to form the intrinsic type layer(s) and the n-type layer(s) in a single chamber. Therefore, in certain embodiments of the system to deposit the second p-i-n junction, the ratio of p-chambers to i/n-chambers is 1:4 or more, such as 1:6 or more. The substrate throughput of the system, including the time to provide plasma cleaning of the process chambers, may be about 3 substrates/hr or more, such as 5 substrates/hr or more.

In certain embodiments of the invention, a system 600 is configured to deposit the WSR layer 112, as depicted in FIG. 1, that may be disposed between a first and a second p-i-n junction or a second p-i-n junction and a second TCO layer. In one embodiment, one of the process chambers 631-637 is configured to deposit one or more of the WSR layers, and another one of the process chambers 631-637 is configured to deposit the p-type layer(s) of the second p-i-n junction while the remaining process chambers 631-637 are each configured to deposit both the intrinsic type layer(s) and the n-type layer(s). The number of the chambers configured to deposit the WSR layer may be similar to the number of the chambers configured to deposit the p-type layer(s). Additionally, the WSR layer may be deposited in the same chamber configured to deposit both the intrinsic type layer(s) and the n-type layer(s).

In certain embodiments, the throughput of a system 600 that is configured for depositing the first p-i-n junction comprising an intrinsic type amorphous silicon layer has a throughput that is two times greater than the throughput of a system 600 that is used to deposit the second p-i-n junction comprising an intrinsic type microcrystalline silicon layer, due to the difference in thickness between the intrinsic type microcrystalline silicon layer(s) and the intrinsic type amorphous silicon layer(s). Therefore, a single system 600 that is adapted to deposit the first p-i-n junction, which comprises an intrinsic type amorphous silicon layer, can be matched with two or more systems 600 that are adapted to deposit a second p-i-n junction, which comprises an intrinsic type microcrystalline silicon layer. Accordingly, the WSR layer deposition process may be configured to be performed in the system adapted to deposit the first p-i-n junction for efficient throughput control. Once a first p-i-n junction has been formed in one system, the substrate may be exposed to the ambient environment (i.e., break vacuum) and transferred to the second system, where the second p-i-n junction is formed. A wet or dry cleaning of the substrate between the first system depositing the first p-i-n junction and the second p-i-n junction may be necessary. In one embodiment, the WSR layer deposition process may be performed in a separate system.

Thus, methods for forming an intrinsic type microcrystalline silicon layer in a solar cell device are provided. The method utilizes multiple step deposition process that provides a first deposition mode and a second deposition mode having pulsed RF power and gas mixture. The method advantageously produces an intrinsic type microcrystalline silicon layer having high crystalline fraction, crystalline uniformity and photoelectric conversion efficiency and device performance of the PV solar cell.

While the foregoing is directed to embodiments of the present invention, other and further embodiments of the invention may be devised without departing from the basic scope thereof, and the scope thereof is determined by the claims that follow.

1. A method for forming an intrinsic type microcrystalline silicon layer, comprising:
providing a substrate into a processing chamber;
supplying a gas mixture into the processing chamber
applying a RF power at a first mode to the gas mixture;
pulsing the gas mixture into the processing chamber; and
applying the RF power at a second mode to the pulsed gas mixture.

2. The method of claim 1, wherein applying the RF power at the first mode further comprises:
depositing an intrinsic type microcrystalline silicon seed layer on the substrate in the presence of the first gas mixture and the first RF power mode.

3. The method of claim 1, wherein pulsing the gas mixture further comprises:
depositing a bulk intrinsic type microcrystalline silicon layer on the substrate.

4. The method of claim 1, wherein applying the RF power at the first mode further comprises:
ramping up RF power supplied into the processing chamber.

5. The method of claim 4, wherein ramping up the RF power further comprises:
ramping up the RF power from a first predetermined range to a second predetermined range during a period of between about 20 seconds and about 300 seconds.

6. The method of claim 5, wherein the first predetermined range of RF power is between about 0 Watts and about 5 KiloWatts and the second predetermined range of RF power is controlled at between about 2 KiloWatts and about 8 KiloWatts.

7. The method of claim 1, wherein supplying the gas mixture further comprises:
supplying the gas mixture into the processing chamber prior to applying the RF power in the first mode.

8. The method of claim 1, wherein supplying the gas mixture further comprises:
ramping up flow rate of the gas mixture supplied into the processing chamber.

9. The method of claim 8, wherein the flow rate of the gas mixture is ramped up to a predetermined set point over a period of between about 20 seconds and about 300 seconds.

10. The method of claim 8, wherein the flow rate of the gas mixture is ramped up from about zero sccm/L to between about 2.8 sccm/L and about 5.6 sccm/L.

11. The method of claim 1, wherein the gas mixture includes at least a silicon based gas and a hydrogen based gas.

12. (canceled)

13. The method of claim 1, wherein pulsing the RF power further comprises:
pulsing the RF power at about every about 0.1 seconds to about 60 seconds.

14. The method of claim 12, wherein pulsing the RF power further comprises:
pulsing the RF power for between about 10 seconds and about 150 seconds.

15. The method of claim 1, wherein pulsing the gas mixture further comprises:
synchronously pulsing the RF power at the second mode while pulsing the gas mixture supplied into the processing chamber.

16. A method for forming an intrinsic type microcrystalline silicon layer, comprising:
providing a substrate into a processing chamber;
supplying a gas mixture into the processing chamber;
applying a RF power to energize the gas mixture;
depositing a seed silicon layer on the substrate surface in the presence of the gas mixture;
subsequent to the depositing of the seed silicon layer, synchronously pulsing the gas mixture and the RF power; and
depositing a bulk silicon layer over the seed silicon layer in the presence of the pulsed gas mixture.

17. The method of claim 16, wherein supplying the gas mixture further comprises:
ramping up flow rate of the gas mixture supplied into the processing chamber.

18. The method of claim 17, wherein ramping up further comprises:
ramping silane flow rate supplied in the gas mixture into the processing chamber.

19. The method of claim 16, wherein applying the RF power further comprising:
ramping up the RF power.

20. The method of claim 19, wherein ramping up the RF power further comprises:
synchronously ramping up the RF power and ramping up the gas mixture.

21. (canceled)

22. A photoelectric device, comprising:
a p-type silicon containing layer;
an intrinsic type microcrystalline silicon layer disposed on the p-type silicon containing layer; and
a n-type silicon containing layer disposed on the intrinsic type microcrystalline silicon layer, wherein the intrinsic type microcrystalline silicon layer is formed by a process comprising:
supplying a gas mixture into the processing chamber having a first RF power mode applied thereto;
depositing an intrinsic type microcrystalline silicon seed layer;
pulsing the gas mixture in the process chamber having a second RF power mode applied thereto; and
depositing a bulk intrinsic type microcrystalline silicon layer over the intrinsic type microcrystalline silicon seed layer.

23. The photoelectric device of claim 22, wherein the intrinsic type microcrystalline silicon seed layer has a higher crystalline fraction than the bulk intrinsic type microcrystalline silicon layer.

24. (canceled)

25. A method for forming an intrinsic type microcrystalline silicon layer, comprising:
providing a substrate into a processing chamber;
gradually ramping up a flow rate of a gas mixture supplied into the processing chamber for a first predetermined time period;
synchronously ramping up a RF power supplied into the gas mixture while ramping up the flow rate the gas mixture; and
depositing an intrinsic type microcrystalline silicon seed layer on the substrate surface.

26. The method of claim 25, further comprising:
controlling the gas mixture supplied to the processing chamber at a steady flow rate for a second predetermined time period after the first predetermined time period is terminated; and
depositing a bulk intrinsic type microcrystalline silicon layer on the substrate.

27. The method of claim 26, wherein controlling the gas mixture further comprises:
controlling the RF power supplied to the processing chamber at a steady power for the second predetermined time period.

28. The method of claim 25, wherein the gas mixture includes at least a silicon based gas and a hydrogen based gas.
